(19) United States
(12) Patent Application Publication
(10) Pub. No.: US 2014/0326970 A1
(43) Pub. Date: Nov. 6, 2014

(54) Host Materials for Single-Layer Phosphorescent OLEDs

(71) Applicants: Zachary M. Hudson, Greely (CA); Suning Wang, Kingston (CA); Michael G. Helander, Toronto (CA); Zhibin Wang, Toronto (CA); Zheng-Hong Lu, Toronto (CA)

(72) Inventors: Zachary M. Hudson, Greely (CA); Suning Wang, Kingston (CA); Michael G. Helander, Toronto (CA); Zhibin Wang, Toronto (CA); Zheng-Hong Lu, Toronto (CA)

(21) Appl. No.: 14/268,292

(22) Filed: May 2, 2014

Related U.S. Application Data
(60) Provisional application No. 61/819,231, filed on May 3, 2013.

(51) Int. Cl. H01L 51/00

(52) U.S. Cl. CPC H01L 51/0067; H01L 51/0072
USPC 257/40; 546/276.7; 544/322

(57) ABSTRACT

New carbazole-based compounds are provided that are useful as host materials for singlelayer and multilayer organic light-emitting diode (OLED) devices. Highly efficient single-layer OLEDs have been demonstrated using new N-heterocyclic carbazole-based host materials. Phosphorescent OLEDs with a structure of ITO/MoO₃/host/host:dopant/host/Cs₂CO₃/Al have been fabricated in which the new host materials act simultaneously as electron-transport, holetransport and host layer. Using this design, devices with maximum current and external quantum efficiencies of 92.2 cd and 26.8% were achieved, the highest reported to date for a single-layer OLED.

### RELATED APPLICATIONS

This application claims the benefit of the filing date of U.S. Provisional Patent Application No. 61/819,231, filed on May 3, 2013, the contents of which are incorporated herein by reference in their entirety.

### FIELD OF THE INVENTION

The invention relates to phosphorescent compounds that are capable of acting as a host layer in an electroluminescent device. The invention more particularly relates to N-heterocyclic carbazole-based compounds.

### BACKGROUND OF THE INVENTION

Bright and efficient organic light-emitting diode (OLED) devices and electroluminescent (EL) devices have attracted considerable interest due to their potential application for flat panel displays (e.g., television and computer monitors) and lighting. OLED-based displays offer advantages over the traditional liquid crystal displays, such as: wide viewing angle, fast response, lower power consumption, and lower cost. Phosphorescent OLEDs (or PhOLEDs) employing late transition metal complexes as emitters are particularly attractive due to their ability to harvest both singlet and triplet excitons, making it possible to achieve internal quantum efficiencies of 100% (see L. Xiao, et al., Adv. Mater. 2010, 23, 926-952; Y. Tao, et al., Chem. Soc. Rev. 2011, 40, 2943-2970; Y. Shirota, et al., Chem. Rev. 2007, 107, 953-1010; Y. Chi, et al., Chem. Soc. Rev. 2010, 39, 638-655; Y. You, et al., Dalton Trans. 2009, 1267-1272; J. A. G. Williams, et al., Coord. Chem. Rev. 2008, 252, 2596-2611; W. Y. Wong, et al., Coord. Chem. Rev, 2009, 253, 1709-1758; W. Y. Wong, et al., J. Mater. Chem. 2009, 19, 4457-4482; M. E. Thompson, MRS Bulletin 2007, 32, 694; M. A. Baldo, et al., in Organic Electroluminescence, Z. H. Kafafi ed., Ch. 6, p. 267. Taylor & Francis: New York, 2005; K. Chen, et al., Chem. Eur. J. 2010, 16, 4315; F.-M. Hwang, et al., Inorg. Chem. 2005, 44, 1344; T. C. Lee, et al., Adv. Funct. Mater. 2009, 19, 2639; Y. H. Song, et al., Chem. Eur. J. 2008, 14, 5423; C. F. Chang, et al., Angew. Chem. Int. Ed. 2008, 47, 4542; and J. Zou, et al., Adv. Mater. 2011, 23, 2976-2980). However, due to the long excited state lifetimes of phosphorescent materials, these emitters must be doped into host matrices to prevent exciton quenching by triplet-triplet annihilation. This doped emissive layer is then typically sandwiched between a hole-transport layer (HTL) and an electron-transport layer (ETL). These layers may be manipulated in order to achieve balanced charge injection into the emission zone. To date, development strategies for achieving high efficiencies in PhOLEDs have focused on such a multilayer device structure.

However, use of multiple layers in an OLED increases the cost of a device. Since materials for each layer must be individually synthesized and carefully purified before being deposited sequentially on a substrate, multilayer devices may mean an expensive and time-consuming fabrication process. Furthermore, care must be taken at every interface within the device to match the appropriate energy levels of all adjacent layers, and to avoid exciplex formation and charge accumulation. These issues present significant challenges to mass production of OLEDs, making a simplified device structure highly desirable.

### SUMMARY OF THE INVENTION

New carbazole-based compounds are provided that are useful as host materials for single-layer and multilayer organic light-emitting diode (OILED) devices. Highly efficient single-layer OLEDs have been demonstrated using new N-heterocyclic carbazole-based host materials. Phosphorescent OLEDs with a structure of ITO/MoO₃/host/host:dopant/host/Cs₂CO₃/Al have been fabricated in which the new host materials act simultaneously as electron-transport, hole-transport and host layer. Using this design, devices with maximum current and external quantum efficiencies of 92.2 cd A⁻¹ and 26.8% were achieved, the higheset reported to date for a single-layer OLED.

A first aspect of the invention provides a compound of general formula:

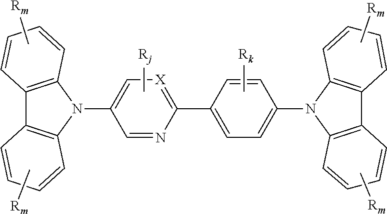

wherein N is nitrogen, X is C or N, each R is independently C₁-C₄ aliphatic, j is 0-3 each m is independently 0-4, and k is 0-4. In an embodiment of this aspect, one or more R is C₁. In another embodiment of this aspect, at least one R is C₁. In another embodiment of this aspect, j+k=1. In another embodiment of this aspect, all of j, k and m are zero. In yet another embodiment of this aspect, the compound is

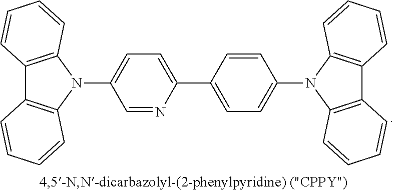 [SMILES: c1ccc2c(c1)c1ccccc1n2-c1ccc(-c2ccc(-n3c4ccccc4c4ccccc43)cn2)cc1]

In another embodiment of this aspect, the compound is

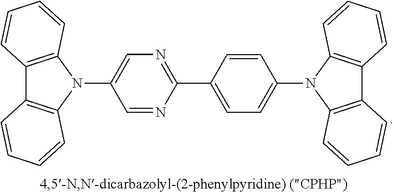 [SMILES: c1ccc2c(c1)c1ccccc1n2-c1ccc(-c2ncc(-n3c4ccccc4c4ccccc43)cn2)cc1]

A second aspect of the invention provides a host material of an EL device comprising a compound of the first aspect or any embodiment thereof. In an embodiment of the second aspect, the energy gap of the HOMO and LUMO energy levels of the host material is greater than the energy gap of the HOMO and LUMO energy levels of an emitter doped in the host material.

A third aspect of the invention provides a single-layer electroluminescent device for use with an applied voltage, comprising a first electrode, a layer which comprises a compound of the first aspect, or any embodiment thereof, doped with an emitter, and a second, transparent electrode, wherein voltage is applied to the two electrodes to produce an electric field across the layer so that the emitter electroluminesces. In some embodiments of this aspect, the host material may also electroluminesce (e.g., weakly relative to the emitter's electroluminescence).

A fourth aspect of the invention provides an electroluminescent device for use with an applied voltage, comprising a first electrode, a second, transparent electrode, an electron transport layer adjacent the first electrode, a hole transport layer adjacent the second electrode, and an emitter doped in a host layer, interposed between the electron transport layer and the hole transport layer, wherein voltage is applied to the two electrodes to produce an electric field across the device so that the emitter electroluminesces, wherein one or more of the electron transport layer, hole transport layer, and host layer comprises a compound of the first aspect or any embodiment thereof.

A fifth aspect of the invention provides a consumer product comprising the device of the one of the aspects of the invention that are described herein. In an embodiment of this aspect, the consumer product comprises a digital display. In certain embodiments, the consumer product is a television, computer monitor, flat or flexible panel display, mobile phone, lighting (including solid-state lighting), timepiece, electronic glasses, game console (e.g., portable game console), or Personal Digital Assistant. In certain embodiments, the consumer product comprises a compound of the first aspect. In some embodiment, the compound included in the consumer product is CPPY or CPHP.

A sixth aspect of the invention provides a photoluminescent product or an electroluminescent product comprising a compound of the first aspect or any embodiment thereof, or the host material of the second aspect. In an embodiment of the sixth aspect, the product is a fiat panel display device or a lighting device. In another embodiment of this aspect, the product is a luminescent probe or sensor.

A seventh aspect of the invention provides a method of producing electroluminescence, comprising the steps of providing a host layer comprising a compound of the first aspect, or any embodiment thereof, doped with an emitter, and applying a voltage across the host layer so that the emitter electroluminesces. In some embodiments of this aspect, the host material may also electroluminesce (e.g., weakly relative to the emitter's electroluminescence). In another embodiment, the compound of the first aspect has an energy gap between its HOMO and LUMO energy levels that is greater than an energy gap of an emitter's HOMO and LUMO energy levels.

An eighth aspect of the invention provides a method of using a compound of the first aspect or any embodiment thereof, as a host material in an EL device (e.g., an OLED). In an embodiment of this aspect, the OLED further comprises an emitter. In another embodiment of this aspect, the OLED further comprises an electron transport layer (ETL). In another embodiment of this aspect, the OLED further comprises a hole transport layer (HTL). In yet another embodiment of this aspect, the OLED further comprises a hole injection layer (HIL) or an electron injection layer (EIL).

A ninth aspect of the invention provides a composition comprising a compound of the first aspect or any embodiment thereof, an organic polymer, and/or a solvent.

A tenth aspect of the invention provides use of a compound of the first aspect or any embodiment thereof as a host material in an EL device, e.g., an OLED.

An eleventh aspect of the invention provides an electroluminescent device for use with an applied voltage, comprising a first electrode, a second, transparent electrode, and an emissive layer, which comprises a host compound as claimed in the above aspects doped with an emitter, that is located between the first and second electrodes, wherein voltage is applied to the two electrodes to produce an electric field across the emissive layer so that the emitter and/or the host compound electroluminesces. In an embodiment of this aspect, the electroluminescent device further comprises an electron transport layer adjacent the first electrode, and a hole transport layer adjacent the second electrode, wherein the emissive layer is interposed between the electron transport layer and the hole transport layer. In embodiments of the eleventh aspect, for the compound of claim 1, at least one R is C₁, j+k=1, at least one of j, k and m are zero, or all of j, k and m are zero. In certain embodiments of the eleventh aspect, the compound of claim 1 is CPPY or CPHP.

### BRIEF DESCRIPTION OF THE DRAWINGS

For a better understanding of the present invention and to show more clearly how it may be carried into effect, reference will now be made by way of example to the accompanying drawings, which illustrate aspects and features according to preferred embodiments of the present invention, and in which:

FIG. 1A shows a crystal structure of CPPY (with only one disordered site for its pyridyl N atom);

FIG. 1B shows a crystal structure of CPHP (with 50% thermal ellipsoids) where nitrogen atoms are shown in white;

FIG. 2A shows absorption spectra for specified compounds at 10⁻⁵ M in CH₂Cl₂ where λₑₓ=340 nm;

FIG. 2B shows emission spectra for specified compounds at 10⁻⁵ M in CH₂Cl₂;

FIG. 3 shows frontier molecular orbital surfaces and calculated orbital energies for CBP (top), CPPY (middle) and CPHP (bottom) with an isocontour value of 0.03;

FIGS. 4A and 4B depict a single-layer OLED structure in two ways: FIG. 4A shows electrodes as vertical lines, with y-axis indicating energy levels of each material's LUMO and HOMO level, and FIG. 4B is a simple layer diagram;

FIGS. 5A-C show (A) current efficiency, (B) power efficiency, and (C) external quantum efficiency for Devices I, II, III and IIIb;

FIG. 6A shows charge transport characteristics of hole-only devices incorporating CBP, CPPY and CPHP, for the device structure shown in FIG. 6B;

FIG. 6B shows a schematic of the device structure for the data shown in FIG. 6A;

FIG. 6C shows UPS spectral data for specified host materials, showing the energy level alignment of each host on ITO/MoO₃;

FIG. 7 shows time-resolved phosphorescence spectra of specified host materials at 10⁻⁵ M in 2-McTHF at 77K with delay=1 ms and λₑₓ=340 nm;

FIG. 8 shows thermogravimetric analyses of the specified host materials;

FIG. 9 shows cyclic voltammograms of the specified host materials; and

FIG. 10 shows a representative EL spectrum for green OLEDs I-IIIb measured at 7.0 V (all four devices' EL spectra showed identical emission profiles).

### DETAILED DESCRIPTION OF THE INVENTION

### Definitions

As used herein, the term “OLED” is an acronym for organic light-emitting diode, which is a diode that emits light when an electric field is applied to its electrodes. An OLED includes an emissive electroluminescent layer situated between two electrodes, which layer is commonly a film that includes an organic (i.e., contains one or more carbon atoms) compound that emits light in response to an electric current. Typically, at least one of the electrodes is transparent. OLEDs are used to create digital displays in devices such as television screens, computer monitors, portable systems such as mobile phones, handheld game consoles and Personal Digital Assistants (PDAs).

As used herein, the term “EL” refers to electroluminescence, in which a material emits light in response to the passage of an electric current or to a strong electric field.

As used herein, the term “CPPY” refers to 4,5′-N,N′-dicarbazolyl-(2-phenylpyridine).

As used herein, the term “CPHP” refers to 4,5′-N,N′-dicarbazolyl-(2-phenylpyrimidine).

As used herein, the term “CBP” refers to 4,4′-N,N′-dicarbazolylbiphenyl.

A “host material” refers to a matrix material that is used in an EL device, such as, for example, an OLED, and that transfers charge and/or energy to an emissive material.

As used herein, the term “HTL” refers to hole transport layer.

As used herein, the term “ETL” refers to electron transport layer.

As used herein, the term “HIL” refers to hole injection layer.

As used herein, the term “EIL” refers to electron injection layer.

As used herein, the term “UPS” refers to ultraviolet photoelectron spectroscopy.

As used herein, the term “HOMO” is an acronym for Highest Occupied Molecular Orbital.

As used herein, the term “LUMO” is an acronym for Lowest Unoccupied Molecular Orbital.

As used herein, the term “hole transfer” refers to a charge migration in which the majority of carriers are positively charged (see IUPAC Gold Book).

As used herein, the term “electron transfer” refers to migration of an electron from one molecular entity to another, or between two localized sites in the same molecular entity (see IUPAC Gold Book).

As used herein, the term “Vₒₙ” refers to turn-on voltage.

As used herein, the term “CEₘₐₓ” refers to maximum current efficiency.

As used herein, the term “PEₘₐₓ” refers to maximum power efficiency.

As used herein, the term “C.I.E. ” refers to Commission Internationale d'Eclairage, and is generally used in regard to chromaticity coordinates.

As used herein, the term “EQE” refers to external quantum efficiency and “EQEₘₐₓ” refers to maximum external quantum efficiency.

As used herein, the term “E_{F}” refers to an energy level, which is known as the Fermi level, at which there is a 50% chance of being occupied at a given temperature.

As used herein “aliphatic” includes alkyl, alkenyl and alkynyl. An aliphatic group may be substituted or unsubstituted. It may be straight chain, branched chain or cyclic.

As used herein “aryl” includes aromatic carbocycles and aromatic heterocycles and may be substituted or unsubstituted.

As used herein “unsubstituted” refers to any open valence of an atom being occupied by hydrogen. Also, if an occupant of an open valence position on an atom is not specified then it is hydrogen.

As used herein “substituted” refers to the structure having one or more substituents.

As used herein “heteroatom” means a non-carbon, non-hydrogen atom, and may be used to denote atoms that have a lone pair of electrons available to form dative or coordinate bonds (e.g., N, O, P, S).

### Embodiments

As described herein, a family of compounds has been discovered that is a suitable host material for electroluminescent devices. This family of compounds is suitable for use in multilayer devices and, surprisingly, is also suitable for single layer devices. As described above, multilayer devices are more costly since each layer must be synthesized, purified and deposited on a substrate. Single layer devices and other simplified devices are desirable since they are easy and less costly to produce.

Only a small number of reports describe preparation of simplified single-layer OLEDs, in which a single layer of organic material is required for a device to function (see K. R. J. Thomas, et al., Adv. Funct. Mater. 2004, 14, 387-392; H. Zhang, et al., Chem. Commun. 2006, 281-283; T. H. Huang, et al., Adv. Mater. 2006, 18, 602-606; M. Lai, et al., Angew. Chem. Int. Ed. 2008, 47, 581-585; C. Chen, et al., Adv. Funct. Mater. 2009, 19, 2661-2670; Z. Liu, et al., Org. Electron. 2009, 10, 1146-1151; Z. Liu, et al., J. Phys. Chem. C 2010, 114, 11931-11935; N. C. Erickson, et al., Appl. Phys. Lett. 2010, 97, 083308; and X. Qiao, et al., J. Appl. Phys. 2010, 108, 034508). Prior to the current discovery, the efficiency of all single-layer devices reported to date was far behind the efficiencies obtained by more complex multilayer devices (see Y. Sun, et al., Nature 2006, 440, 908; S. Reineke, et al., Nature 2009, 459, 234-238; Z. B. Wang, et al., Nature Photon. 2011, 5, 753). This inefficiency of prior single layer-devices has been due primarily to the difficulty of developing a host material that is not only capable of balanced carrier transport but that also possesses a HOMO level that is well-matched to the anode and a LUMO level that is well-matched to the cathode. Bipolar host materials have both electron- and hole-transporting functionalities. Such host materials show promise, as careful selection and modification of the transporting moieties can provide good carrier balance (see Y. Tao, et al., Angew. Chem. Int. Ed. 2008, 47, 8104-8107; F. Hsu, et al., Adv. Funct. Mater. 2009, 19, 2834-2843; Z. Q. Gao, et al., Adv. Mater. 2009, 21, 688-692; H. Chou, et al., Adv. Mater. 2010, 22, 2468-2471; M. M. Rothmann, et al., Org. Electron. 2011, 12, 1192-1197; C. Cai, et al., Org. Electron. 2011, 12, 843-850; A. Chaskar, et al., Adv. Mater. 2011, 23, 3876-3895; and Y. Chen, et al., J. Mater. Chem. 2011, 21, 14971-14978). Though bipolar host materials have been the subject of recent research, examples of their use in single-layer OLEDs remains rare (see T. H. Huang, et al., Adv. Mater. 2006, 18, 602-606; M. Lai, et al., Angew. Chem. Int. Ed. 2008, 47, 581-585; C. Chen, et al., Adv. Funct. Mater. 2009, 19, 2661-2670; X. Qiao, et al., J. Appl. Phys. 2010, 108, 034508; and Y. Sun, et al., Nature 2006, 440, 908).

Effective host materials for phosphorescent OLEDs have qualities that provide device reliability, and include: (i) triplet energies higher than those of doped emitters to prevent reverse energy transfer (from emitter to host material) and thus confine triplet excitons on emitters; (ii) balanced charge transporting properties with appropriate HOMO/LUMO energy levels; and (iii) good thermal stability. Also, important factors for single-layer PhOLEDs include a host material that has: a suitable energy level match to the OLED's cathode/anode for easy charge injection; balanced electron and hole mobilities for large charge flux and efficient charge recombination; and high triplet energy relative to emitting phosphors for exciton confinement within the emissive layer.

Carbazole-based molecules have been reported as host materials in OLEDs. Carbazole-based molecules can have high triplet energy and hole-transporting functionality (see K. Wong, et al., Org. Lett. 2005, 7, 5361-5364; M. H. Tsai, et al., Adv. Mater. 2006, 18, 1216-1220; M. H. Tsai, et al., Adv. Mater. 2007, 19, 862-866; S. Su, et al., Chem. Mater. 2008, 20, 1691-1693; T. Tsuzuki, et al., Appl. Phys. Lett. 2009, 94, 033302; J. He, et al., J. Phys. Chem. C 2009, 113, 6761-6767; H. Fukagawa, et al., Adv. Mater. 2010, 22, 4775-4778; P. Schrogel, et al., J. Mater. Chem. 2011, 21, 2266-2273; T. Motoyama, et al., Chem. Lett. 2011, 40, 306-308; and C.-L. Ho, et al., J. Mater. Chem. 2012, 22, 215-224). In particular, 4,4′-N,N′-dicarbazolylbiphenyl (CBP) is used as a host material for phosphorescent emitters. It has also recently been demonstrated that CBP may be used directly as an HTL in both fluorescent and phosphorescent OLEDs (Z. B. Wang, et al., Appl. Phys. Lett. 2011, 98, 073310). For example, a phosphorescent OLED with >20% external quantum efficiency (EQE) at a high luminance of >10,000 cd/m² has been demonstrated in a bilayer device using CBP directly as hole transport layer as well as host material (Z. B. Wang, et al., Appl. Phys. Lett. 2011, 98, 073310). Since no additional injection layers and exciton blocking layers were needed, the resultant device structure was highly simplified. This simple structure also helped to eliminate redundant organic/organic interfaces near the exciton formation zones, at which charge carriers could accumulate and ultimately quench excitons. However, electron transport by CBP is relatively inefficient, resulting in poor electron injection from commonly used Cs₂CO₃/Al or LiF/Al cathodes and making necessary a discrete electron transport layer. Thus, while CBP can he used to fabricate highly efficient double-layer devices, additional chemical modification to promote electron transport would be required to achieve a new material capable of acting as HTL, ETL, and host material.

The new family of compounds described herein provides high performance in a simplified device structure, employing a single material as HTL, ETL, and host material. As described herein, the inventors have succeeded in designing and synthesizing a family of compounds in which: (i) the LUMO level is lowered relative to CBP, reducing the barrier to electron injection at the cathode, ii) the HOMO energy is not significantly changed relative to CBP, preserving efficient hole injection at the anode, and iii) the triplet level remains significantly large making it suitable for use with phosphorescent dopants. That is, the energy gap of the HOMO and LUMO energy levels of the host material is greater than the energy gap of the HOMO and LUMO energy levels of an emitter doped in the host.

A general formula for such materials is provided below.

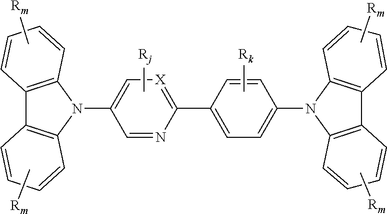

wherein N is nitrogen;
X is C or N;
each R is independently C₁-C₄ aliphatic;
j is 0-3;
each m is independently 0-4; and
k is 0-4.

The inventors designed and synthesized two exemplary compounds of the above general formula, namely, 4,5′-N,N′-dicarbazolyl-(2-phenylpyridine) (“CPPY”) and 4,5′-N,N′-dicarbazolyl-(2-phenylpyrimidine) (“CPHP”) (shown below with CBP for comparison). These two novel host materials have been synthesized and fully characterized including examination by ¹H and ¹³C NMR spectroscopy, mass spectrometry, DFT calculations, X-ray crystallographic analysis, and ultraviolet photoelectron spectroscopy (UPS).

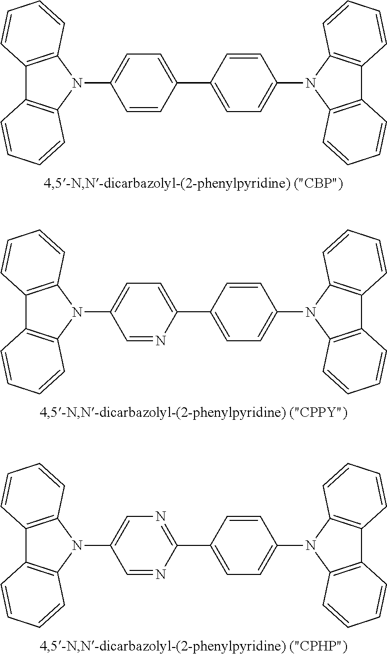 [SMILES: c1ccc2c(c1)c1ccccc1n2-c1ccc(-c2ccc(-n3c4ccccc4c4ccccc43)cc2)cc1 ; c1ccc2c(c1)c1ccccc1n2-c1ccc(-c2ccc(-n3c4ccccc4c4ccccc43)cn2)cc1 ; c1ccc2c(c1)c1ccccc1n2-c1ccc(-c2ncc(-n3c4ccccc4c4ccccc43)cn2)cc1]

As shown above, CPPY and CPHP have structural differences in the bridging moiety (which is biphenyl in CBP). These differences are sufficient to significantly improve electron injection and transport. Exemplary single layer electroluminescent devices with CPPY and CPHP were prepared and tested. These single layer OLEDs exhibited the highest efficiencies for single layer OLEDs that have been reported to date. These examples of single-layer OLEDs with efficiencies competitive with traditional multilayer devices are described herein.

The single-layer devices had the structure ITO/MoO₃/host/host:dopant/host/Cs₂CO₃/Al. These devices employed ITO/MoO₃ and Cs₂CO₃/Al as composite electrodes and Ir(ppy)₂(acac) as the dopant (i.e., phosphorescent emitter). With this structure, a peak EQE of 26.8% and current efficiency of 92.2 cd/A were achieved, remaining as high as 21.3% and 73.3 cd/A at the practical brightness of 100 cd/m⁻².

Although a single-layer device is desirable as described above, there may be applications where a multi-layer device is also of use. Accordingly, devices that include a host layer comprising a compound of the general formula described herein, and one or more of: an electron transport layer (ETL), a hole transport layer (HTL), an electron injection layer (EIL), and a hole injection layer (HIL) are also envisioned by the inventors.

Exemplary host compounds CPPY and CPHP were synthesized in two steps. The first step was palladium-catalyzed Suzuki coupling of 4-bromophenylboronic acid with an appropriate heteroaryl halide. The second step was copper-catalyzed Ullman condensation. This second step proceeded with good yield. Both CPPY and CPHP show thermal stabilities by thermogravimetric analysis, that are comparable to that of CBP (see Table 1). The introduction of electronegative nitrogen atoms to the π-system of CBP lowered the LUMO energy, while leaving the HOMO level largely unchanged. Substitution of CBP with one or two nitrogen atoms was found to reduce the LUMO level by 0.19 and 0.33 eV respectively, with no significant change in the HOMO level in either case as measured by UPS.

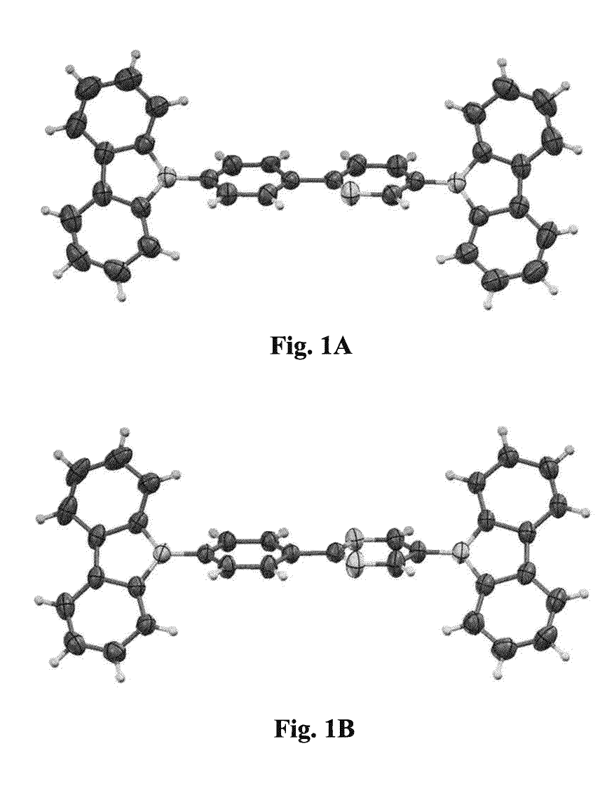

Referring to FIGS. 1A and 1B, X-ray crystal structural analysis was conducted for CPPY and CPHP. This structural analysis confirmed that CPPY and CPHP have essentially identical structures to that of CBP (P. J. Low, et al., J. Mater. Chem. 2005, 15, 2304-2315) with the two central aryl rings being virtually coplanar. In fact, the crystals of CPPY and CBP were isomorphous with similar unit cell parameters and an identical space group, P2₁/c. This is possible due to two-site disordering of the pyridyl nitrogen atom of CPPY over two inversion center-related sites. Although the crystal of CPHP contains CH₂Cl₂ solvent molecules and is thus not readily comparable with CPPY and CBP, it is reasonable to suggest that intermolecular interactions of CPHP in the amorphous solid should be similar due to the similar molecular size and shape of these three molecules.

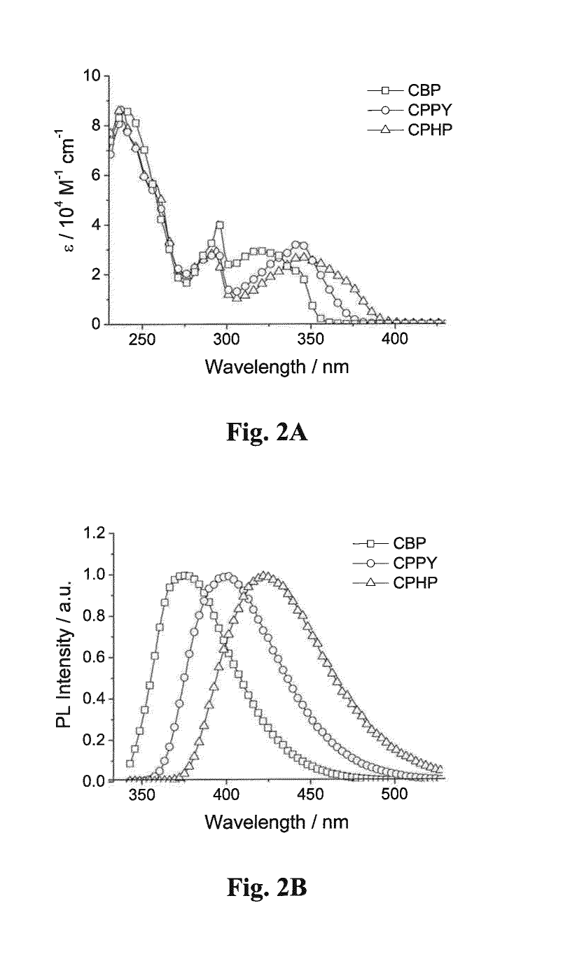

Referring to FIG. 2, absorption and emission spectra of CBP, CPPY and CPHP are shown. The spectra display a clear progression to lower energy as the number of aromatic nitrogen atoms was increased. Triplet energies of these materials were also determined from the first vibronic peak in their time-resolved phosphorescent spectra at 77K (see Table 1), and suggest that these materials are appropriate host materials for red, green, or blue (e.g., sky-blue) emitters.

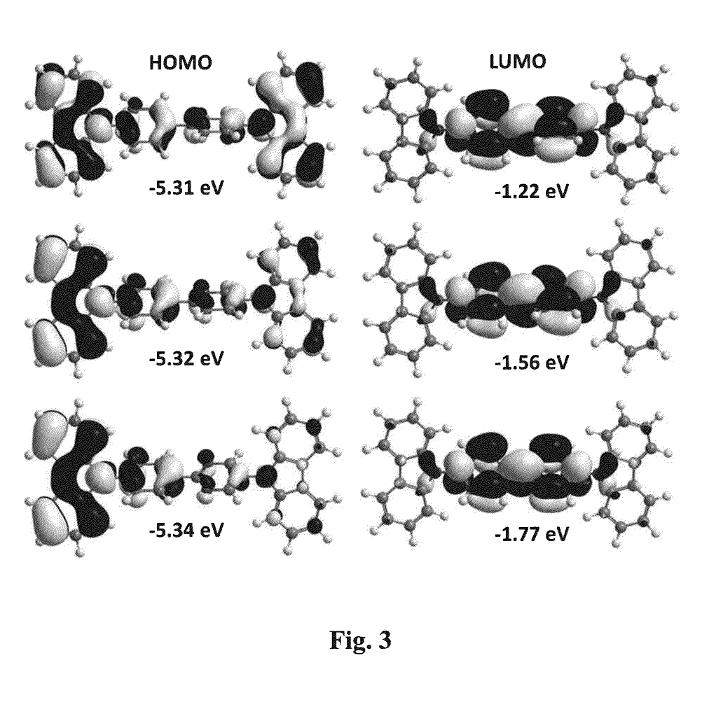

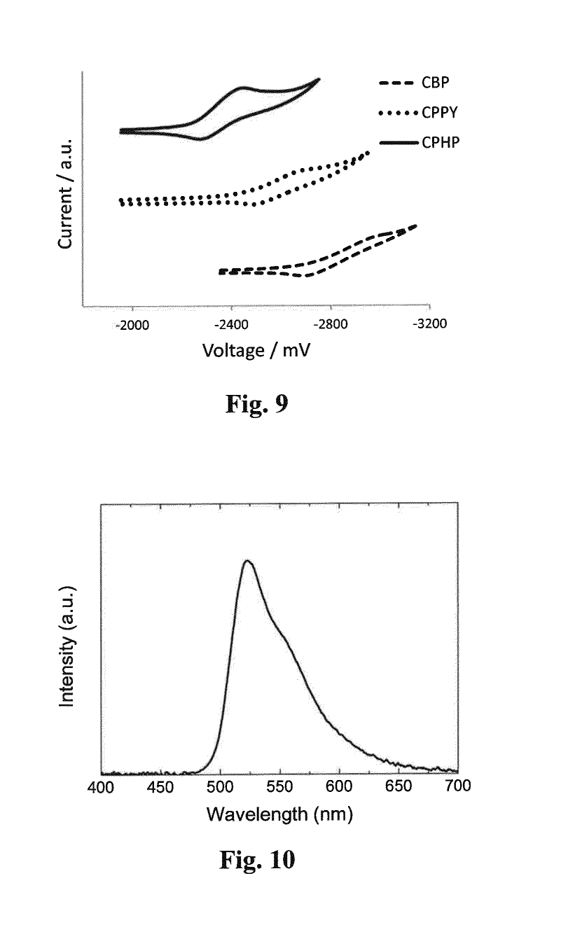

Referring to FIG. 3, electronic properties of CPPY and CPHP were also compared with that of CBP using density functional theory (DFT) calculations (M. J. Frisch et al, Gaussian 03, Revision C.02, Gaussian, Inc., Wallingford, Conn., 2004) at the B3LYP level of theory with 6-31 g* as the basis set. Consistent with UPS data, almost no change is predicted in the HOMO level upon introduction of nitrogen atoms at the 2- and 6-positions of the CRP biphenyl ring system, as the electron density in the HOMO is primarily located on the carbazole functional groups. However, as the LUMO of CBP consists primarily of the π* orbitals of the biphenyl unit, the introduction of these electron-deficient nitrogen atoms is predicted to lower the LUMO level, as observed experimentally. See discussion of FIG. 9 regarding cyclic voltammetry measurements.

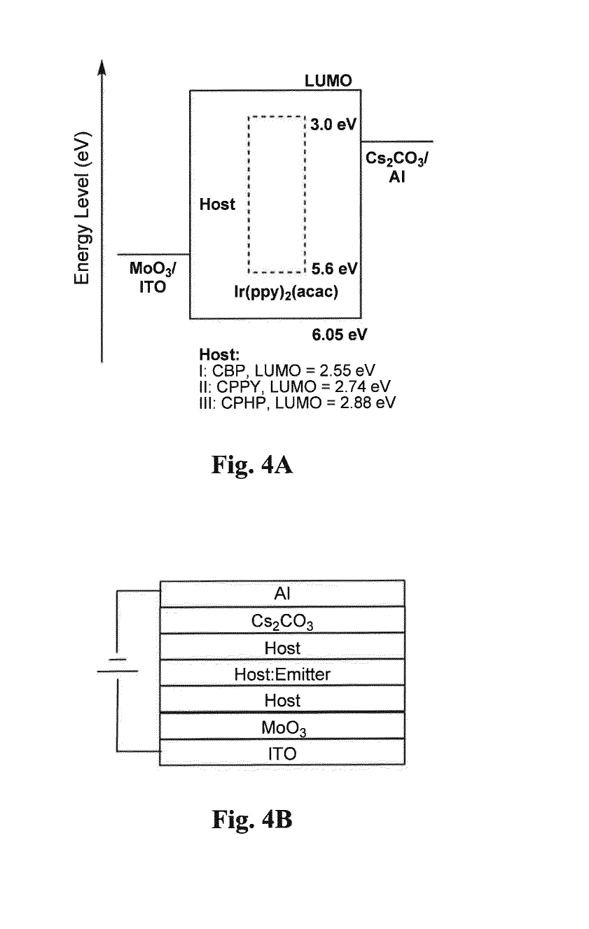

Referring to FIG. 4, to evaluate the performance of these compounds in OLEDs, a series of devices were fabricated in which a thin layer of the doped host material was deposited between two undoped buffer layers of the same host material, which act also as the ETL and HTL in this design. These devices have the following structures:

| Device | Structure |
|---|---|
| I | ITO/MoO₃ (1 nm)/host (35 nm)/host: emitter (8 wt %, 15 |
| | nm)/host (60 nm)/Cs₂CO₃ (1 nm)/Al where host is CBP and |
| | emitter is Ir(ppy)₂(acac). |
| II | ITO/MoO₃ (1 nm)/host (35 nm)/host: emitter (8 wt %, 15 |
| | nm)/host (60 nm)/Cs₂CO₃ (1 nm)/Al where host is CPPY and |
| | emitter is Ir(ppy)₂(acac). |
| III | ITO/MoO₃ (1 mn)/host (35 nm)/host: emitter (8 wt %, 15 |
| | nm)/host (60 nm)/Cs₂CO₃ (1 mn)/Al where host is CPHP and |
| | emitter is Ir(ppy)₂(acac). |
| IIIb | ITO/MoO₃ (1 nm)/host (35 nm)/host: emitter (55 nm)/host (20 |
| | nm)/Cs₂CO₃ (1 nm)/Al where host is CPHP and emitter is |
| | Ir(ppy)₂(acac). |

All of the above devices showed green emission with a peak wavelength of 523 nm and Commision Internationale de l'Éclairage (C.I.E.) coordinates of (0.32, 0.64) (see the electroluminescence spectrum in FIG. 10), indicating that emission originates substantially from the Ir(ppy)₂(acac) dopant in all cases (also see Table 2).

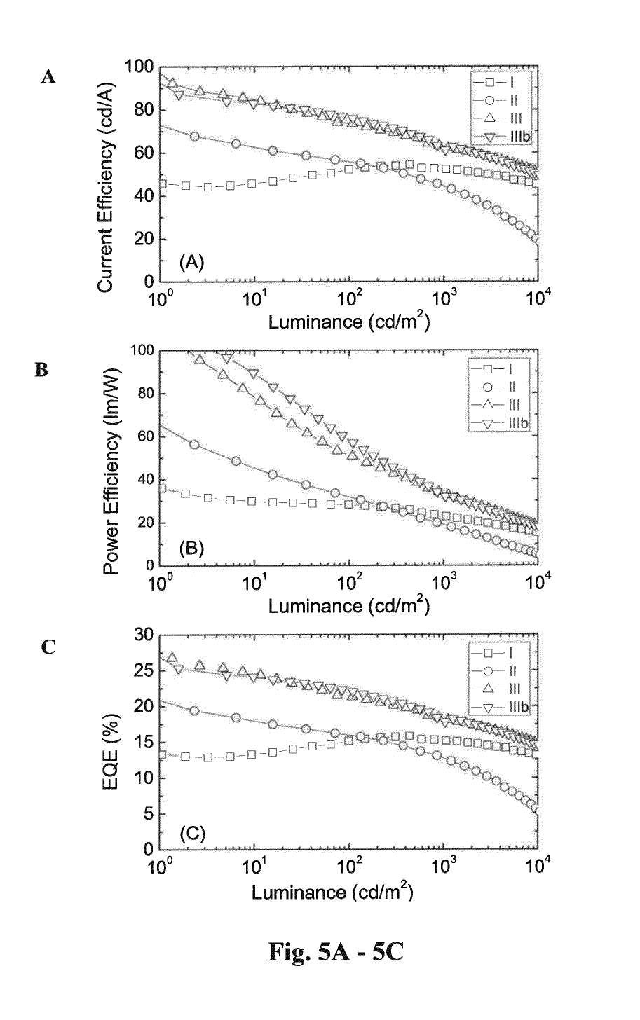

Referring to FIGS. 5A-C, performance of these devices was compared. Notably, alter optimization of each layer thickness it was possible to achieve a high efficiency single-layer OLED simply using CBP as host material. Device I shows a peak EQE of 13.3% and current efficiency of 54.4 cd/A at 438 cd/m², with a moderate turn-on voltage of 4.0 V. Device II incorporating CPPY as host material outperforms the CBP-based device at low luminance, with a peak current efficiency of 74.9 cd/A, EQE of 21.5%, and turn-on voltage of 3.8 V. However, due to significant efficiency roll-off, Device I shows better performance at higher luminance (>200 cd/m²). The performance of Device III, however, shows good performance at all voltages examined, giving a high peak EQE and current efficiency of 26.8% and 92.2 cd/A, remaining as high as 21.3% and 73.3 cd/A at the practical brightness of 100 cd/m². Furthermore, this device shows a significantly lower turn-on voltage of 3.0 V, confirming that the lower LUMO level of CPHP does indeed reduce the barrier to electron injection at the cathode. This is the most efficient simplified single-layer OLED reported to date by a factor of two or more (K. R. J. Thomas, et al., Adv. Fund. Mater. 2004, 14, 387-392; H. Zhang, et al., Chem. Commun. 2006, 281-283; T. H. Huang, et al., Adv. Mater. 2006, 18, 602-606; M. Lai, et al., Angew. Chem. Int. Ed. 2008, 47, 581-585; C. Chen, et al., Adv. Funct. Mater. 2009, 19, 2661-2670; Z. Liu, et al., Org. Electron. 2009, 10, 1146-1151; Z. Liu, et al., J. Phys. Chem. C 2010, 114, 11931-11935; N. C. Erickson, et al., Appl. Phys. Lett. 2010, 97, 083308; and X. Qiao, et al., J. Appl. Phys. 2010, 108, 034508), and most importantly, shows performance comparable to state-of-the-art devices based on conventional multilayer architectures (Y. Sun, et al., Nature 2006, 440, 908; S. Reineke, et al., Nature 2009, 459, 234-238; and Z. B. Wang, et al., Nature Photon. 2011, 5, 753).

Since no organic/organic heterojunctions are present to facilitate exciton formation in these single-layer devices, there should be a distribution of exciton formation in the host layer. The inventors thus sought to determine if a broader emission zone doped with phosphorescent emitter could more effectively overlap with the exciton formation zone, thus further enhancing device efficiency. Device IIIb was fabricated with a structure of ITO/MoO₃ (1 nm)/CPHP (35 nm)/CPHP:Ir(ppy)₂(acac) (55 nm)/CPHP (20 nm)/Cs₂CO₃ (1 nm)/Al, using CPHP as host material as in Device III but incorporating a much wider 55 nm doped region. The performance of this device is also shown in FIGS. 5A-C, and is compared with Device III. No significant improvement was achieved by broadening the emission zone; that is, doping in a wider region did not enhance the efficiency of an already optimized single-layer device.

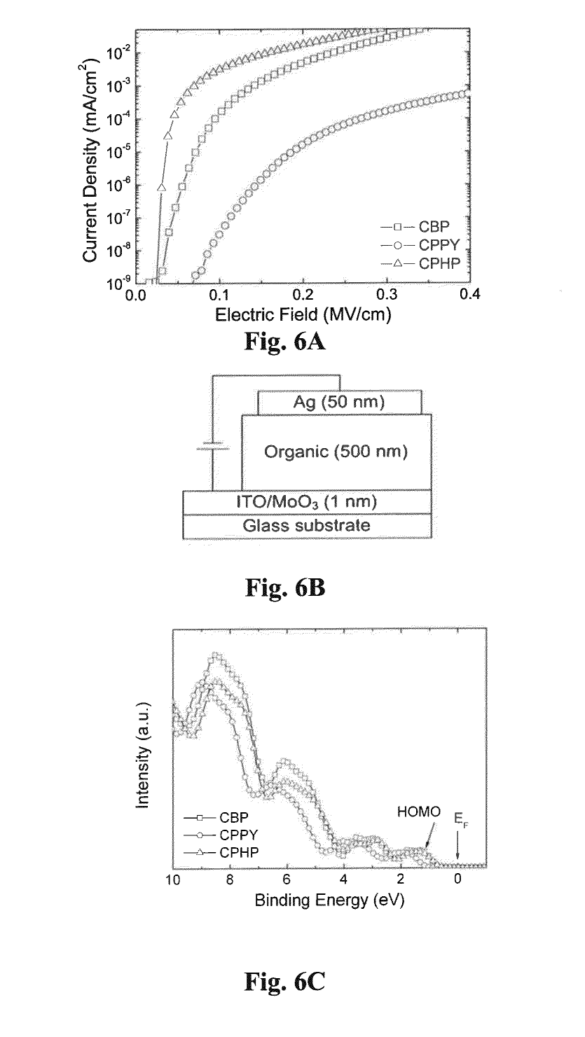

Based on the HOMO and LUMO levels of CPPY the performance of Device II should have been between that of CBP and CPHP. To determine the origins of the significant efficiency roll-off in Device II, the inventors fabricated single carrier hole-only devices to investigate the transport and injection of charge in the three different host materials. The performance of these three devices was compared in FIGS. 6A-B. Notably, the electrical characteristics of the device with CPPY are worse, which suggests either poor injection or transport of holes in this material. This most likely accounts for the significant efficiency roll-off in Device II due to poor electron-hole balance, particularly at high current and brightness. To determine if the poor electrical performance of CPPY was due to poor hole injection or transport the inventors measured the energy-level alignment at the interface with the ITO/MoO₃ anode using UPS.

Referring to FIGS. 6A-B, ultraviolet photoelectron spectroscopy (UPS) valance band spectra are shown of the frontier orbitals of the three different host materials deposited on MoO₃. Although the HOMO level relative to vacuum is the same for the three materials (−6.05 eV), the energy-level alignment is significantly different for CPPY. The HOMO derived peak in the valence band of CPPY is ˜0.5 eV further from the Fermi level than for either CBP or CPHP, which indicates a significantly increased barrier to hole injection at the anode, consistent with the single carrier and OLED performance data. Owing to the similar structures of the three host materials, the reason for this radically different energy-level alignment is likely quite subtle. Among this series of materials, CPPY alone possesses a transverse dipole moment perpendicular to the molecular long axis, yet exhibits molecular packing isostructural with CBP by X-ray crystallography. However, the presence of this dipole moment may result in a preferred molecular orientation at the organic/MoO₃ interface, which may change the energy level alignment. Recent studies have shown that the dipole moments of structurally similar materials can have a dramatic effect on their performance in electroluminescent devices (C.-L. Chiang, et al., Adv. Fund. Mater. 2008, 18, 248-257), and although not wishing to be bound by theory, the inventors propose that similar phenomena are at play here.

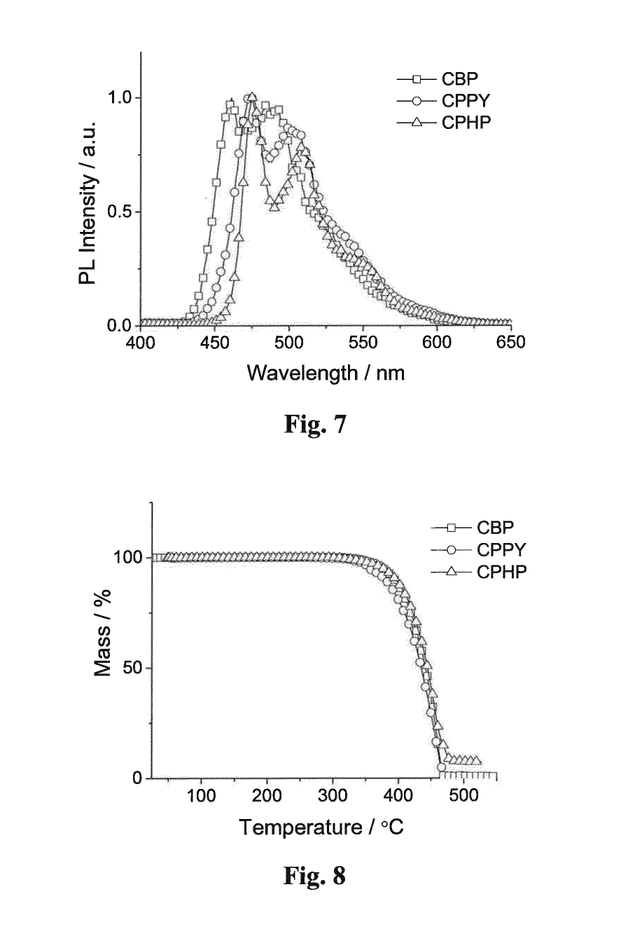

Referring to FIG. 7, a time-resolved phosphorescence spectra is shown of specified host materials at 10⁻⁵ M. The phosphorescence spectra of the host materials at low temperature provide their triplet energy levels (see left edge of peaks). Organic materials are capable of phosphorescence too, but their phosphorescence lifetimes are typically really long (i.e., several seconds), so is typically quenched before it is seen. By cooling a sample, thermal quenching can be reduced/eliminated, allowing for visible phosphorescence. In contrast, an emitter such as Ir(ppy)₃ phosphoresces for a few microseconds, so the phosphorescence is visible at room temp.

Referring to FIG. 8, thermogravimetric analyses are shown of host materials CPPY and CPHP relative to CBP. These plots show the mass of a sample of each host versus temperature, and indicate the temperature at which each material decomposes. Specifically, the plots indicate that both CPPY and CPHP have similar thermal stability to CBP, and are stable up to ˜330° C.

Referring to FIG. 9, LUMO level lowering is further verified by cyclic voltammetry measurements in DMF solution, which clearly indicate improved electron accepting ability in the order of CPHP>CPPY>CBP. Examination of the frontier MO surfaces of these three molecules also reveals increasing bipolar character moving from CBP to CPPY to CPHP. As the central biaryl unit becomes more electron-deficient, the HOMO exhibits increased electron density on the carbazole group farther from the central heteroaromatic ring, with the LUMO showing increased contribution from the N-heterocycle. This imparts more charge-transfer character to CPPY and CPHP, accounting for the larger Stokes shift observed for these molecules.

Referring to FIG. 10 a representative EL spectrum is shown for green OLEDs I-IIIb, measured at 7.0 V. Only a representative spectrum is shown since all four devices' EL spectra showed identical emission profiles.

Many products are known that include an OLED. Compounds of the described general formula may be included in such products. Examples of products that include one or more OLEDs include: televisions, computer monitors, lighting including solid-state lighting, flat panel displays, mobile phones, timepieces, electronic glasses, game consoles including portable game consoles, and Personal Digital Assistants.

Preparation of OLEDs may include preparing a thin film to form a layer. Accordingly, the invention encompasses a composition comprising a compound of the general formula described herein, an organic polymer, and/or a solvent.

In summary, new carbazole-based host materials of the general formula described herein have been demonstrated to be useful for providing simplified single-layer OLEDs with unprecedented performance. Examples of compounds of the general formula include 4,5′-N,N′-dicarbazolyl-(2-phenylpyridine) (CPPY) and 4,5′-N,N′-dicarbazolyl-(2-phenylpyrimidine) (CPHP). As described in the Working Examples, both materials were prepared in good yield by a two-step Suzuki coupling/Ullman condensation route. Devices based on these host materials using Ir(ppy)₂(acac) as emitter exhibited maximum external quantum efficiencies of 21.5% and 26.8%, respectively. These values represent the highest reported to date for a simplified single-layer device. Experimental and theoretical studies confirmed that the LUMO energies of these materials are notably lower than the commonly used host material CBP, while the HOMO energies remained largely unchanged. This design facilitates improved electron injection and transport while preserving hole-transporting functionality, resulting in bipolar host materials with significantly improved device efficiencies. Based on these results the inventors demonstrated that single-layer OLEDs with performance comparable to those of conventional multilayer devices was achievable by careful control of charge transport within the host material and the energy level alignment of the host material at metal/organic interfaces.

It will be understood by those skilled in the art that this description is made with reference to certain preferred embodiments and that it is possible to make other embodiments employing the principles of the invention which fall within its spirit and scope as defined by the claims.

### WORKING EXAMPLES

All reactions were carried out under a nitrogen atmosphere. Reagents were purchased from Aldrich chemical company and used without further purification. Solvents were freshly distilled over appropriate drying reagents. Thin Layer Chromatography was carried out on SiO₂ (silica gel F254, Whatman). ¹H and ¹³C NMR spectra were recorded on Bruker Avarice 400, 500 or 600 MHz spectrometers. Deuterated solvents were purchased from Cambridge Isotopes and used without further drying. Emission spectra were recoded using a Photon Technologies International QuantaMaster Model 2 spectrometer. UV-visible absorbance spectra were recorded using a Varian Cary 50 UV-visible absorbance spectrophotometer. Crystal structures were obtained at 180K using a Bruker AXS Apex II X-ray diffractometer (50 kV, 30 mA, Mo Kα radiation). The synthesis of 4,4′-dibromo-2-phenylpyridine has been reported previously (A. S. Voisin-Chiret, et al., Tetrahedron 2010, 66, 8000-8005).

### Example 1

### EL Device Fabrication

All materials were purified by train sublimation prior to deposition. Devices were fabricated in a Kurt J. Lesker LUMINOS cluster tool with a base pressure of 10⁻⁸ Torr without breaking vacuum. The ITO anode is commercially patterned and coated on glass substrates 50×50 mm² with a sheet resistance less than 15Ω/square. Substrates were ultrasonically cleaned with a standard regiment of Alconox, acetone, and methanol followed by UV ozone treatment for 15 min. The active area for all devices was 2 mm². The film thicknesses were monitored by a calibrated quartz crystal microbalance. Current-voltage (I-V) characteristics were measured using a HP4140B picoammeter in ambient air. Luminance measurements and EL spectra were taken using a Minolta LS-110 luminance meter and an Ocean Optics USB200 spectrometer with bare fiber, respectively. The external quantum efficiency of EL devices was calculated following the standard procedure (S. R. Forrest, et al., Adv. Mater., 2003, 15, 1043-1048). After deposition, single carrier devices were transferred to a homebuilt variable temperature cryostat for measurement at 298K. UPS measurements were performed using a PHI 5500 MultiTechnique system, with attached organic deposition chamber with a basepressure of 10⁻¹⁰ Torr. Additional details regarding device fabrication, characterization and UPS measurements have been described elsewhere (M. G. Helander, et al., Rev. Sci. Instrum. 2009, 80, 033901; and M. G. Helander, et al., Appl. Surf. Sci. 2010, 256, 2602).

### Example 2

### Synthesis

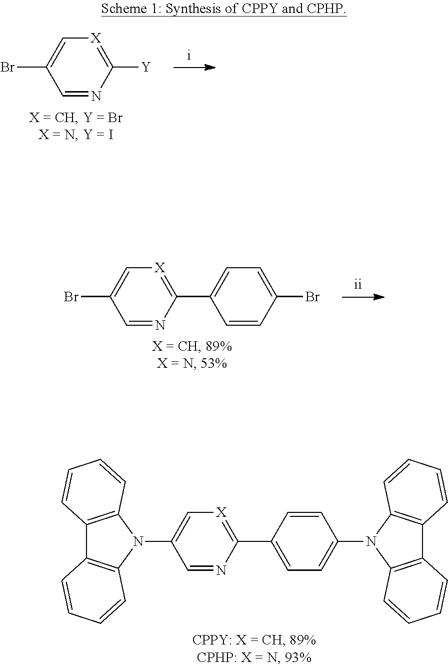

### Reagents and Conditions:

i): 4-bromophenylboronic acid (1 equiv.), K₂CO₃ (3 equiv.), Pd(PPh₃)₄ (5 mol % THF:H₂O, 55° C., 16 h;
ii) Carbazole (3 equiv.), Cu powder (4 equiv.), 18-crown-6 (0.2 equiv.), K₂CO₃ (8 equiv,), o-dichlorobenzene, 185° C., 7 d.

Synthesis of 4,4′-dibromo-2-phenylpyrimidine: To a 250 mL Schlenk flask with condenser and magnetic stir bar was added 4-bromophenylboronic acid (1.4 g, 7.0 mmol), 5-bromo-2-iodopyrimidine (2.0 g, 7.0 mmol), Pd(PPh₃)₄ (240 mg, 0.21 mmol) K₂CO₃ (2.9 g, 21 mmol) and 120 mL degassed 1:1 THF/H₂O. The mixture was heated to 55° C. with stirring for 16 h, after which the THF was removed in vacuo and the aqueous layer were extracted with CH₂Cl₂. Combined hydrophobic layers were dried with MgSO₄, concentrated, and the resultant residue was purified by column chromatography on silica (2:1 hexanes:CH₂Cl₂ as eluent). When the eluent had been removed in vacuo a white solid was obtained and characterized (1.03 g, 53% yield). ¹H NMR (500 MHz, CDCl₃) δ 8.80 (s, 2H, Pyr), 8.27 (d, J=8.5 Hz, 2H, Ph), 7.60 (d, J=8.5 Hz, 2H, Ph) ppm; 162.0, 157.9, 132.5, 131.9, 129.7, 126.0, 118.5 ppm; High Resolution Mass Spectrometry (HRMS) Calc'd for C₁₀H₆Br₂N₂: 311.8898, found 311.8891.

Synthesis of host materials CPPY and CPHP: To a 100 mL Schlenk flask equipped with a magnetic stir bar and condenser was added the desired dibromobiaryl (2.9 mmol), carbazole (1.44 g, 8.6 mmol), K₂CO₃ (3.2 g, 23 mmol), Cu powder (0.73 g, 11.5 mmol) 18-crown-6 (0.15 g, 0.58 mmol) and 30 mL of degassed 1,2-dichlorobenzene. The resultant mixture was heated to reflux at 185° C. for 7 days, at which point the solvent was removed by vacuum distillation. The resultant residue was then extracted with saturated aqueous NH₄Cl, and CH₂Cl₂. The combined hydrophobic layers were dried with MgSO₄, filtered, concentrated and the resultant residue was purified on silica (3:2 CHCl₃:hexanes as eluent) to give the desired compound.

Characterization of 4,5′-N,N′-dicarbazolyl-(2-phenylpyridine) (CPPY): Yield 89%. ¹H NMR (400 MHz, CDCl₃) δ 9.02 (d, J=2.4 Hz, 1H, Py), 8.35 (d, J=8.4 Hz, 2H, Ph), 8.18 (d, J=7.8 Hz, 2H, Cz), 8.17 (d, J=7.6 Hz, 2H, Cz), 8.08 (d, J=8.4 Hz, 1H, Py), 8.04 (dd, J=8.4 Hz, 2.4 Hz, 1H, Py), 7.76 (d, J=8.4 Hz, 2H, Ph), 7.53 (d, J=8.1 Hz, 2H, Cz), 7.50-7.43 (m, 6H, Cz), 7.38-7.30 (m, 4H, Cz) ppm; ¹³C {¹H}NMR (100 MHz, CDCl₃) δ 156.2, 148.3, 140.7, 140.6, 138.8, 137.4, 135.1, 133.4, 128.5, 127.3, 126.3, 126.1, 123.8, 123.6, 121.1, 120.64, 120.57, 120.4, 120.2, 109.8, 109.4 ppm; HRMS calc'd for C₃₅H₂₃N₃: 485.1892, found 485.1883.

Characterization of 4,5′-N,N′-dicarbazolyl-(2-phenylpyrimidine) (CPHP): Yield 93%. ¹H NMR (400 MHz, CDCl₃) δ 9.13 (s, 2H, Pyr), 8.80 (d, J=8.6 Hz, 2H, Ph), 8.19 (d, J=7.6 Hz, 2H, Cz), 8.17 (d, J=7.6 Hz, 2H, Cz), 7.79 (d, J=8.6 Hz, 2H, Ph), 7.55 (d, J=8.2 Hz, 2H, Cz), 7.52-7.43 (m, 6H, Cz), 7.38 (t, J=7.1 Hz, 2H, Cz), 7.32 (t, J=7.5 Hz, 2H, Cz) ppm; ¹³C {¹H} NMR (100 MHz, CDCl₃) γ 162.2, 155.4, 140.5, 140.4, 140.3, 135.6, 131.4, 130.0, 127.0, 126.6, 126.1, 124.1, 123.7, 121.2, 120.8, 120.4, 120.3, 109.9, 109.1 ppm; HRMS calc'd for C₃₄H₂₂N₄: 485.1892, found 486.1852.

### Example 3

### X-Ray Crystal Structural Analysis

See FIGS. 1A and 1B for schematics of the crystal structures. Single crystals of CPPY and CPHP were mounted on glass fibers and were collected on a Bruker Apex II single-crystal X-ray diffractometer with graphite-monochromated Mₒ K_{α} radiation, operating at 50 kV and 30 mA and at 180 K. Data were processed on a computer with the aid of Bruker SHELXTL software package (version 5.10) and corrected for absorption effects. All non-hydrogen atoms were refined anisotropically. Molecules of CPHP co-crystallized with CH₂Cl₂ solvent molecules (0.5 CH₂Cl₂ per CPHP). Because of the disordering of the solvent molecules, they were removed to improve the quality of the crystal data using the Platon Squeeze routine (see A. L. Spek, Acta Cryst. 1990, A46, C34 and PLATON—a Multipurpose Crystallographic Tool, Utrecht University, Utrecht, The Netherlands, A. L. Spek (2006)). Molecules of CPPY possess crystallographically imposed inversion center symmetry. As a result, the pyridyl nitrogen atom was disordered over two sites related by an inversion center. This disordering was modelled and refined successfully.

TABLE 1
Photophysical Properties of Host Materials

| | λ_{max, abs} | λ_{max, fluo.} | λ_{max, phos.} | | E_{T} | T_{d} | HOMO | LUMO |
|---|---|---|---|---|---|---|---|---|
| Cmpd | (nm)^{[a]} | (nm)^{[a]} | (nm)^{[b]} | Φ_{f}^{[c]} | (eV) | (° C.) | (eV)^{[d]} | (eV)^{[e]} |
| CBP | 241, 295, 319, | 374 | 467 | 0.61 | 2.67 | 407 | −6.05 | −2.55 |
| | 342 | | | | | | | |
| CPPY | 238, 294, 343 | 399 | 474 | 0.70 | 2.62 | 395 | −6.05 | −2.74 |
| CPHP | 238, 258, 293, | 425 | 475 | 0.24 | 2.61 | 403 | −6.05 | −2.88 |
| | 343 | | | | | | | |

^{[a]}Measured at 10⁻⁵M in CH₂Cl₂ at 298K.
^{[b]}Measured in 2-MeTHF at 77K.
^{[c]}Relative to 9,10-diphenylanthracene (Φ = 0.90), ±10%.
^{[d]}Measured in the solid state by UV photoelectron spectroscopy.
^{[e]}Calculated from the HOMO level and the optical energy gap.

TABLE 2
Device Performance

| Device | I | II | III | IIIb |
|---|---|---|---|---|
| Vₒₙ (V) | 4.0 | 3.8 | 3.0 | 2.8 |
| CEₘₐₓ (cd A⁻¹) | 54.4 | 74.9 | 92.2 | 87.3 |
| PEₘₐₓ | 36.0 | 56.3 | 106.1 | 107.7 |
| (lm W⁻¹) | | | | |
| EQEₘₐₓ (%) | 13.3 | 21.5 | 26.8 | 25.3 |
| C.I.E. (x, y) | (0.32, 0.64) | (0.32, 0 64) | (0.32, 0.64) | (0.32, 0.64) |

We claim:

1. A compound of general formula: 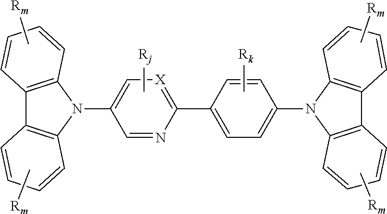
wherein N is nitrogen;
X is C or N;
each R is independently C₁-C₄ aliphatic;
j is 0-3;
each m is independently 0-4; and
k is 0-4.

2. The compound of claim 1, wherein at least one R is C₁.

3. The compound of claim 1, wherein j+k=1.

4. The compound of claim 1, wherein all of j, k and m are zero.

5. The compound of claim 4, which is

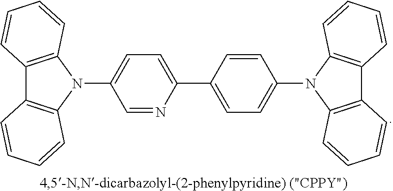 [SMILES: c1ccc2c(c1)c1ccccc1n2-c1ccc(-c2ccc(-n3c4ccccc4c4ccccc43)cn2)cc1]

6. The compound of claim 4, which is

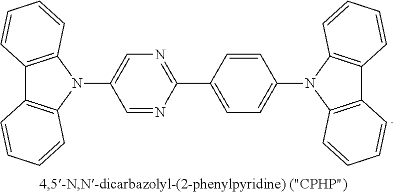 [SMILES: c1ccc2c(c1)c1ccccc1n2-c1ccc(-c2ncc(-n3c4ccccc4c4ccccc43)cn2)cc1]

7. The compound of claim 1, wherein an energy gap between the compound's HOMO and LUMO energy levels is greater than an energy gap of an emitter's HOMO and LUMO energy levels.

8. A electroluminescent device for use with an applied voltage, comprising:
a first electrode,
a second, transparent electrode, and
an emissive layer, which comprises a host compound as claimed in claim 1 doped with an emitter, that is located between the first and second electrodes,
wherein voltage is applied to the two electrodes to produce an electric field across the emissive layer so that the emitter and/or the host compound electroluminesces.

9. The electroluminescent device of claim 8, further comprising:
an electron transport layer adjacent the first electrode, and
a hole transport layer adjacent the second electrode,
wherein the emissive layer is interposed between the electron transport layer and the hole transport layer.

10. A consumer product comprising the device of claim 8.

11. The consumer product of claim 10, comprising a digital display.

12. The consumer product of claim 11, wherein the product is a television, computer monitor, flat panel display, mobile phone, lighting including solid-state lighting, timepiece, electronic glasses, game console, luminescent probe or sensor, or Personal Digital Assistant.

13. The consumer product of claim 8, wherein the compound of claim 1 is CPPY or CPHP.

14. A method of producing electroluminescence, comprising the steps of: providing a host layer comprising a compound as claimed in claim 1 doped with an emitter, and applying a voltage across the host layer so that the host layer electroluminesces.

15. The method of claim 14, wherein for the compound of claim 1 an energy gap between the compound's HOMO and LUMO energy levels is greater than an energy gap of an emitter's HOMO and LUMO energy levels.

16. The method of claim 14, wherein for the compound of claim 1, at least one R is C₁.

17. The method of claim 14, wherein for the compound of claim 1, j+k=1.

18. The method of claim 14, wherein for the compound of claim 1, at least one of j, k and m are zero.

19. The method of claim 14, wherein for the compound of claim 1, all of j, k and m are zero.

20. The method of claim 14, wherein the compound of claim 1 is CPPY or CPHP.
